(19) United States
(12) Patent Application Publication
(10) Pub. No.: US 2025/0346028 A1
(43) Pub. Date: Nov. 13, 2025

(54) CORROSION-SUSCEPTIBLE BONDING LAYER IN ASSISTING SEMICONDUCTOR WAFER DEBONDING

(71) Applicant: Micron Technology, Inc., Boise, ID (US)

(72) Inventors: Kyle K. Kirby, Eagle, ID (US); Andrew M. Bayless, Boise, ID (US); Kunal R. Parekh, Boise, ID (US)

(21) Appl. No.: 19/199,389

(22) Filed: May 6, 2025

Related U.S. Application Data
(60) Provisional application No. 63/644,400, filed on May 8, 2024.

(51) Int. Cl. B32B 43/00; H01L 21/683

(52) U.S. Cl. CPC B32B 43/006; B32B 2457/14; H01L 21/6835

(57) ABSTRACT

A bonded semiconductor structure including a product wafer having a first metal layer disposed on a first frontside surface of the product wafer, and a carrier wafer having a second metal layer disposed on a second frontside surface of the carrier wafer and a third metal layer disposed under the second metal layer, wherein the first metal layer is bonded to the second metal layer by metal-metal bonds disposed at a bonding interface between the first frontside surface and the second frontside surface, and wherein the third metal layer includes a corrosion portion extending from an edge of the carrier wafer to a center of the carrier wafer.

### CROSS-REFERENCE TO RELATED APPLICATION(S)

The present application claims priority to U.S. Provisional Patent Application No. 63/644,400, filed May 8, 2024, the disclosure of which is incorporated herein by reference in its entirety.

### TECHNICAL FIELD

The present disclosure generally relates to semiconductor wafer debonding and more particularly relates to facilitating semiconductor wafer debonding through introducing a corrosion-susceptible bonding layer close to the bonding interface.

### BACKGROUND

Semiconductor wafers bonding and debonding are foundational technologies in modern semiconductor fabrication, enabling the creation of advanced semiconductor assembly and devices with improved performance, reduced size, and new functionalities. During a wafer bonding process, two or more semiconductor wafers are joined together using various bonding techniques such as fusion bonding, adhesive bonding, and others. Debonding is a process of separating bonded wafers after necessary processing has been completed. Various techniques including mechanical debonding, thermal slide debonding, and laser debonding can be adopted to physically separate the wafers. Often time the wafer debonding process can be challenging, especially in temporary bonding applications where a carrier wafer needs to be removed.

### BRIEF DESCRIPTION OF THE DRAWINGS

FIGS. 1A and 1B are partially schematic, cross-sectional views of bonded semiconductor wafers having a corrosion-susceptible bonding layer at the bonding interface in accordance with various embodiments of the present technology.

FIGS. 2A to 2G are partially schematic, cross-sectional side views of semiconductor wafers during semiconductor wafer bonding and debonding processes in accordance with various embodiments of the present technology.

FIGS. 3A to 3H are partially schematic, cross-sectional side views of semiconductor wafers during semiconductor wafer bonding and debonding processes in accordance with various embodiments of the present technology.

FIGS. 4A to 4C are top down views of semiconductor wafers having various structures of corrosion-susceptible bonding layers in accordance with various embodiments of the present technology.

FIG. 5 is a partially schematic, cross-sectional view of bonded semiconductor wafers each having a corrosion-susceptible metal layer in accordance with various embodiments of the present technology.

FIG. 6 is a flow chart illustrating a method for bonding and debonding semiconductor wafers in accordance with various embodiments of the present technology.

FIG. 7 is a partially schematic block diagram of a system that includes a semiconductor device configured in accordance with various embodiments of the present technology.

### DETAILED DESCRIPTION

The wafer debonding process is a critical step in the fabrication of semiconductor devices, especially for those utilizing thin wafers and advanced packaging technologies. Semiconductor wafer debonding process presents several challenges that can impact manufacturing yield, device performance, and reliability. For example, the expansion coefficients of different materials on the bonded semiconductor wafers can vary, leading to thermal stress during the heating and cooling phases. The thermal stress contained in the bonded wafers can cause warping, cracking, or delamination of the materials when separating the wafers. In addition, applying mechanical force to separate the bonded wafers can lead to breakage or induce micro-cracks in the wafers, particularly for very thin wafers. Ensuring uniform force application without damaging the wafer is a significant challenge. Further, certain wafer bonding process may form a strong bonding interface (e.g., with chemical bonds having a high bond energy) between the bonded wafers, making the downstream wafer debonding process extremely hard.

To solve the issues and challenges described above, the present technology implements a pre-positioned material into the wafer bonding structure. The pre-positioned material can be corroded, during a debonding process, through corrode galvanic, corrosion, or self-perpetuating chemical reactions. The chemical reactions of pre-positioned material may be driven by a catalyst or specific operation conditions of the debonding operation. In one embodiment, a corrosion-susceptible metal layer is buried below a thin metal bonding layer that is disposed on either one of a carrier wafer or a product wafer. During the debonding process, an edge region of the bonded wafers can be exposed to corrosive gases to trigger the buried metal layer chemical reaction. Corrosion regions can be formed at the wafer edge region and extending towards the wafer center. The buried metal layer can be a continuous film or patterned structure and is introduced to facilitate the detaching of product wafer from carrier wafer at the corroded metal layer. In another embodiment, a dielectric layer can be buried below a thin metal bonding layer on a carrier wafer. One or more vias can be formed at wafer edge region and connected to the buried dielectric layer. During a wafer debonding process, a voltage can be applied on the buried dielectric layer, at the bonded wafer edge and through the one or more vias, to cause dielectric break down in the dielectric layer. The dielectric layer break down weakens a strengthen of the buried dielectric layer and facilitates a following wafer debonding process.

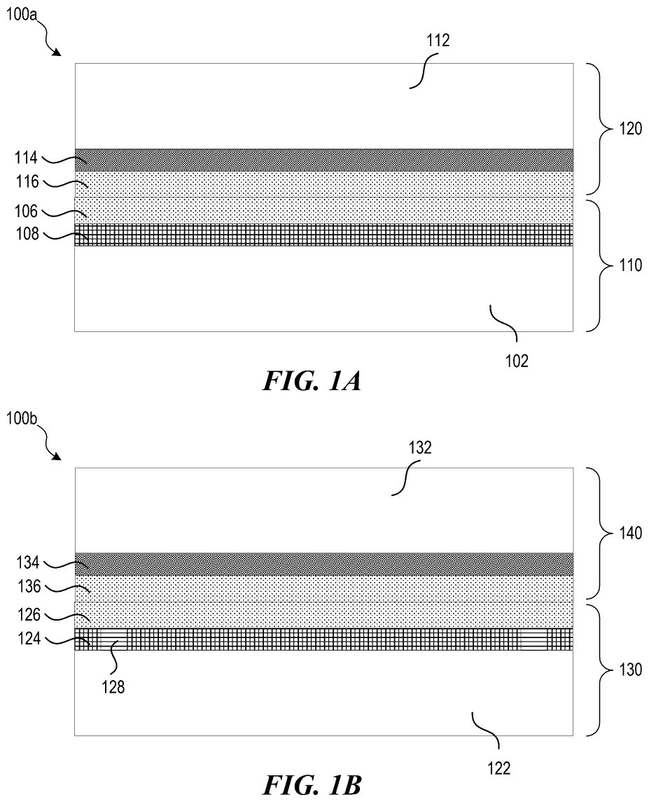

FIGS. 1A and 1B are partially schematic, cross-sectional views of bonded semiconductor wafers having a corrosion-susceptible bonding layer at the bonding interface in accordance with various embodiments of the present technology. For example, FIG. 1A shows a schematic cross-sectional view of a product wafer 120 bonded on a carrier wafer 110. In this example, the carrier wafer 110 includes a metal layer 106 disposed above the frontside surface of the substrate 102 and a metal layer 108 that is buried/disposed under the metal layer 106. Here, the metal layer 108 is corrosion-susceptible and includes a corrosion portion extends internally from the edge of the carrier wafer 110. As shown in FIG. 1A, the product wafer 120 includes a dielectric layer 114 deposited above a substrate 112, the dielectric layer 114 having device structures such as transistors, passive components, and/or electrical interconnections embedded therein. In addition, the product wafer 120 includes a metal layer 116 disposed above the dielectric layer 114. In some examples, the one or more device structures are formed on the surface of the substrate 112 closer to the dielectric layers 114. In some alternative examples, the one or more device structures are formed on the surface that is opposite the dielectric layer 114.

In this example, the product wafer 120 and the carrier wafer 110 are bonded through metal-metal bonding between the metal layers 106 and 116. Each of the metal layers 106 and 116 can be made of materials including titanium, tantalum, tungsten, copper, aluminum, or a combination thereof. In some other examples, each of the metal layers 106 and 116 can be patterned and have dielectric materials deposited therein (not shown). The dielectric materials can have a frontside surface coplanar to the frontside surface of corresponding metal layer. Specifically, the dielectric materials embedded in the metal layers 116 and 106 can be aligned during a hybrid wafer bonding process and form dielectric-dielectric bonding at the bonding interface. In some other examples, one or more dielectric layers (not shown) can be deposited above the metal layers 106 and 116. A dielectric-dielectric bonding can be formed between the dielectric layers of the product wafer 120 and the carrier wafer 110.

In this example, the metal layer 108 of the carrier wafer is corrosion-susceptible and can be corroded by corrosive chemistries such as chlorine, hydrogen, fluorine, or a combination thereof. In addition, the metal layers 108 and 106 are made of different materials. Here, a corrosion portion of the metal layer 108 extends from the edge to the center of the carrier wafer 110. A faster etch rate/higher etch selectivity on the metal layer 108 is preferred and can be adjusted, in comparison to the substrates 102 and 112 and other metal layers exposed at wafer edge, by controlling the processing temperature and/or corrosive gas flow rate, etc. The corrosion portion of the metal layer 108 may include copper chloride (CuCl₂), tungsten hexachloride (WCl₆), aluminum trichloride (AlCl₃), and/or dimeric aluminum chloride (Al₂Cl₆). The structure and stability of molecular compounds of the corrosion portion of the metal layer 108 (e.g., Al₂Cl₆) depends on the molecular geometry and distribution of electrons around the molecule, which can be energetically less favorable as efficient packing and bonding in metallic material (e.g., Al). As a result, the bonded semiconductor wafers 110 and 120 are easier to be debonded, i.e., through the corrosion portion of the metal layer 108, in comparison to a debonding process through bonded interfacial metal layers 106 and 116. Further, the metal layer 108 may have a thickness ranging from 10 nm to 100 um. The corrosion portion of the metal layer 108 may have a thickness close to the carrier wafer and a width up to 12 inches.

In the bonded semiconductor structure shown in FIG. 1A, metal silicide materials can be formed at the bonding interface, e.g., between the metal layers 106 and 116. The metal silicide material may contain metallic elements diffused from the underneath metal layer 108 and provides a relatively higher electrical conductivity. In this example, the metal silicide materials can be made of tungsten silicide, copper silicide, aluminum silicide, and/or thereof.

FIG. 1B shows a schematic cross-sectional view of another product wafer 140 bonded on another carrier wafer 130. In this example, the carrier wafer 130 includes a metal layer 126 disposed above the frontside surface of the substrate 122 and a dielectric layer 124 that is buried/disposed under the metal layer 126. Here, the dielectric layer 124 can be made of materials including silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In addition, the dielectric layer 124 includes one or more vias 128 that are disposed close to the edge of the carrier wafer 130. The vias 128 can be filled by electrically conductive materials such as tungsten, copper, aluminum, or a combination thereof. As shown in FIG. 1B, the product wafer 140 includes a dielectric layer 134 deposited above a substrate 132, the dielectric layer 134 having device structures such as transistors, passive components, and/or electrical interconnections embedded therein. In addition, the product wafer 140 includes a metal layer 116 above the dielectric layer 134. Each of the metal layers 136 and 126 can be made of titanium, tantalum, tungsten, copper, aluminum, or a combination thereof. In this example, the product wafer 140 is bonded on the carrier wafer 130 through metal-metal bonding at the interface between the metal layers 126 and 136. In some examples, the one or more device structures are formed on the surface of the substrate 132 closer to the dielectric layers 134. In some alternative examples, the one or more device structures are formed on the surface that is opposite the dielectric layer 134.

In this example, the dielectric layer 124 of the carrier wafer 130 can be completely break down or partially break down. For example, the dielectric layer 124 may include defects or imperfections such as voids, holes, and/or grain boundaries that can concentrate an electric field and convert the dielectric layer 124 from dielectric isolating to electrically conductive. Further, the dielectric layer 124 can include one or more breakdown regions close to the vias 128. Moreover, the dielectric breakdown in the dielectric layer 124 can be caused by introducing a high voltage, at the bonding interface metal layers 136 and 126 and through the vias 128, to the dielectric layer 124. The electrically conductive vias 128 can track a localized electric field therearound and cause formation of microvoids or cracks within the dielectric layer 124. Here, the dielectric breakdown can significantly impact the strength of the dielectric layer 124 and facilitate a wafer debonding process. In this example, the dielectric layer 124 may have a thickness ranging from 10 nm to 100 um. As shown in FIG. 1B, the vias 128 can have a frontside surface coplanar with the frontside surface of the dielectric layer 124. Additionally, the vias 128 may have a thickness similar to or less than the thickness of the dielectric layer 124.

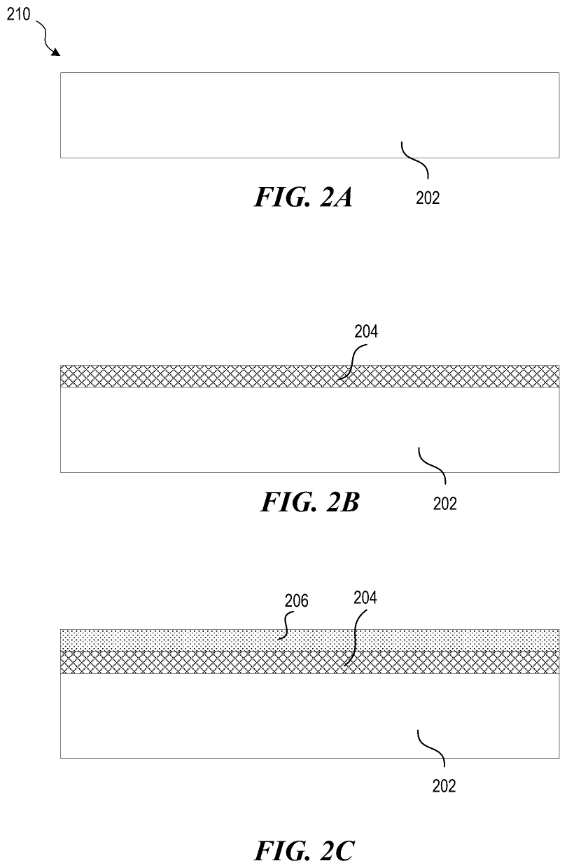

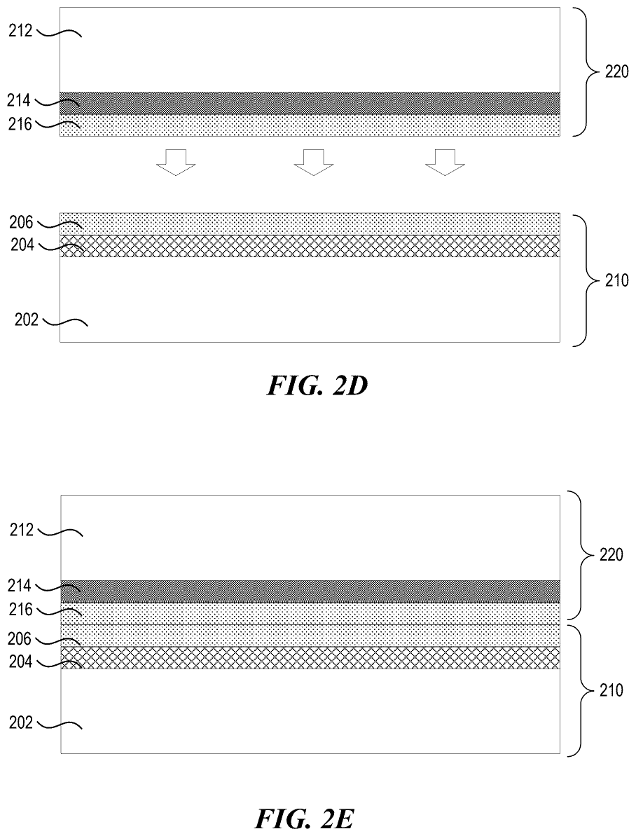

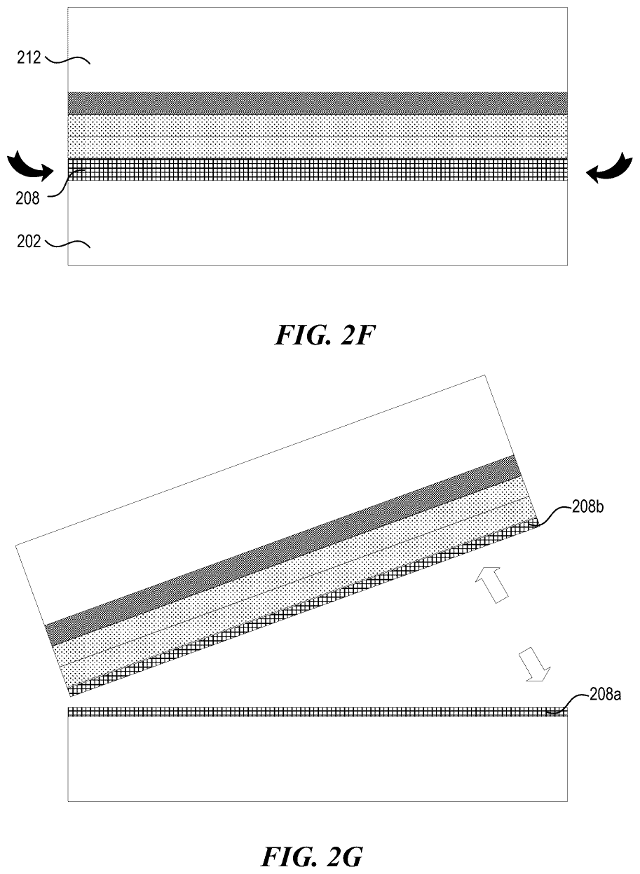

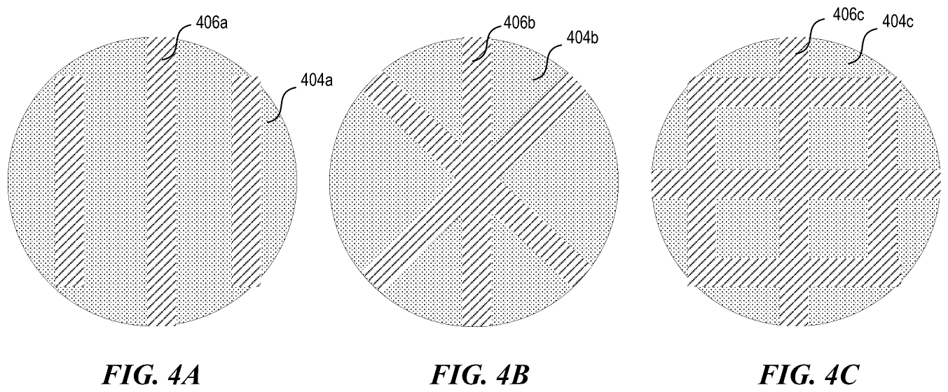

FIGS. 2A to 2G are partially schematic, cross-sectional side views of semiconductor wafers during semiconductor wafer bonding and debonding processes in accordance with various embodiments of the present technology. In particular, FIGS. 2A to 2C illustrate steps of fabricating a carrier wafer 210 having a corrosion-susceptible metal layer 204. In this example, the metal layer 204 can be deposited on a frontside surface of the substrate 202. Thin film deposition techniques such as chemical vapor deposition (CVD), physical vapor deposition (PVD), and/or atomic layer deposition (ALD) processes can be used to fabricate the metal layer 204. In addition, the metal layer 204 can have a thickness ranging from 10 nm to 100 um. In a next step shown in FIG. 4C, another metal layer 206 can be deposited above the metal layer 204 and includes different metallic elements to the metal layer 204. Similarly, the metal layer 206 can be deposited using thin film deposition techniques including CVD, PVD, and/or ALD processes. Here, each of the metal layers 204 and 206 can be made of materials including titanium, tantalum, tungsten, copper, aluminum, or a combination thereof. The metal layer 206 has a flat frontside surface and has a thickness ranging from 100 nm to 500 μm. In this example, it is preferrable to select specific metal materials for the metal layers 204 and 206 so that there is an etching selectivity therebetween under corrosion chemistries such as chlorine, hydrogen, fluorine, or a combination thereof. For example, the metal layer 204 can be made of aluminum and the metal layer 206 can be made of copper. Because the intrinsic reactivity of aluminum with Cl₂ is higher than that of copper, the metal layer 204 can be etch more rapidly than copper under similar conditions. In a downstream etching process, the volatility of etching by products also plays a role, e.g., a higher volatility of AlCl₃ etch by product makes the removal of aluminum more efficient in comparison to copper etching by products such as CuCl or CuCl₂.

FIGS. 2D and 2E illustrate steps of bonding a product wafer 220 onto the carrier wafer 210. As shown, the product wafer 220 is upside down and facing towards the carrier wafer 210. Similar to the product wafer 120 shown in FIG. 1A, the product wafer 220 includes a substrate 212, a dielectric layer 214 deposited above the substrate 212, and a metal layer 216 disposed above the dielectric layer 214. The dielectric layer 114 includes device structures such as transistors, passive components, and/or electrical interconnections embedded therein. In addition, the metal layer 216 can be made of materials including titanium, tantalum, tungsten, copper, aluminum, or a combination thereof. Specifically, the metal layers 216 and 206 can be made of a same metal materials in order to strengthen the bonding strengthen between the product wafer 220 and carrier wafer 210. The bonded semiconductor structure is shown in FIG. 2E, within which the metal layers 216 and 206 are bonded (e.g., through a fusion bonding process) and form metal-metal bonds therebetween.

In some examples, a stack of semiconductor device layers can be bonded on the carrier wafer 210. For example, multiple product wafers can be stacked onto each other and bonded to the carrier wafer 210, after the product wafer 220 is bonded to the carrier wafer 210 as described in FIG. 2E. Specifically, the substrate 212 of the product wafer 220 can be thinned front its backside, e.g., using wafer grinding processes such as a mechanical grinding process and/or a CMP process. After that, another product wafer can be bonded to the thinned product wafer 220, e.g., through bonding a frontside surface of the additional product wafer to the backside surface of the product wafer 220 to form a front to back (F2B) bonding interface therebetween. These processes can be repeated multiple times to form a stacked semiconductor device layers above the carrier wafer 210.

FIGS. 2F and 2G illustrate steps of debonding the product wafer 220 from the carrier wafer 210. In this example, corrosive gases can be introduced into a process chamber in where the bonded semiconductor structure including the product wafer 220 and the carrier wafer 210 is located, as shown in FIG. 2F. In particularly, one or more corrosive gases can be flowed to exposed portion of the metal layer 204 at the edge of the carrier wafer 210. Here, the corrosive gases can be chlorine, hydrogen, fluorine, or a combination thereof. Moreover, the corrosive gases have chemical interactions with the metal layer 204, form the etch towards the center of the carrier wafer 210, and generate etch by-products. A faster etch rate/higher etch selectivity on the metal layer 204 can be achieved by adjust the etching process temperature and/or corrosive gas flow rate, etc. The corrosion changes the metal layer 204 into a deteriorated metal layer 208 which includes corrosion regions. The corrosion regions may be disposed at the edge of the carrier wafer 210 and extends into the center of the carrier wafer 210. In this example, the corrosion of metal layer 204 can be a self-perpetuating, extending from the edge towards the center of the carrier wafer 210. To further enhance the corrosion on metal layer 204, specific catalysts or environmental conditions can be adopted to accelerate the corrosion process. In the case of chlorine-induced corrosion, the presence of moisture can greatly accelerate the process, as chlorine can be highly reactive when combined with water, forming hydrochloric acid (HCl) and other corrosive agents. Alternatively, a local laser ablation process can be conducted at the bonded wafer edge region, e.g., the exposed metal layer 204, to form metal silicide comprising tungsten silicide, copper silicide, and/or aluminum silicide.

In this example, the corrosion regions of metal layer 208 can include copper chloride (CuCl₂), tungsten hexachloride (WCl₆), aluminum trichloride (AlCl₃), and/or dimeric aluminum chloride (Al₂Cl₆). Here, the structure and stability of molecular compounds of the corroded metal layer 208 is weaker than the original metal layer 204, because the deteriorated metal layer 208 (e.g., Al₂Cl₆) includes molecular geometry and distribution of electrons that are energetically less favorable than efficient packing and bonding in metallic materials (e.g., Al). As a result, the bonded semiconductor wafers 210 and 220 can be debonded in an easier manner, i.e., through the corrosion portion of the metal layer 208, as shown in FIG. 2G. Various debonding techniques such as mechanical debonding, laser debonding, chemical debonding, thermal debonding, and/or UV release debonding can be used in this process to break the corroded metal layer 208. The corroded meta layer 208 in this example facilitates the wafer debonding process because it requires a lower debond force to detach the product wafer 220 from the carrier wafer 210, which in turn achieves a higher debonding process yield. After the debonding process, residual corrosion byproducts the corroded metal layer 208 such as copper chloride (CuCl₂), tungsten hexachloride (WCl₆), aluminum trichloride (AlCl₃), dimeric aluminum chloride (Al₂Cl₆), and/or a combination thereof can be disposed on the debonded surfaces of the product wafer and carrier wafer, e.g., the residue metal layer 208a and 208b. In a downstream cleaning/planarization process, the residue metal layer 208a and 208b can be removed using a wet chemical cleaning process or a chemical mechanical polish (CMP) process. Further, the carrier wafer 210 can be reused for another wafer bonding process. In some examples, the debonded product wafer 220 may include a stack of semiconductor device layers with multiple permanent bonded interfaces disclose therebetween.

In this example, the debonded product wafer 220 can be sent to downstream processes to complete a semiconductor device. The semiconductor device may include one or more metal layers (e.g., layers 206 and 216) deposited above a dielectric layer (e.g., layer 214). In addition, the semiconductor device may include one or more layers subjected to corrosive chemistry or one or more debonded surfaces that underwent corrosive chemistry. For example, the semiconductor device may include the residue metal layer 208b that is disposed above the metal layer 206.

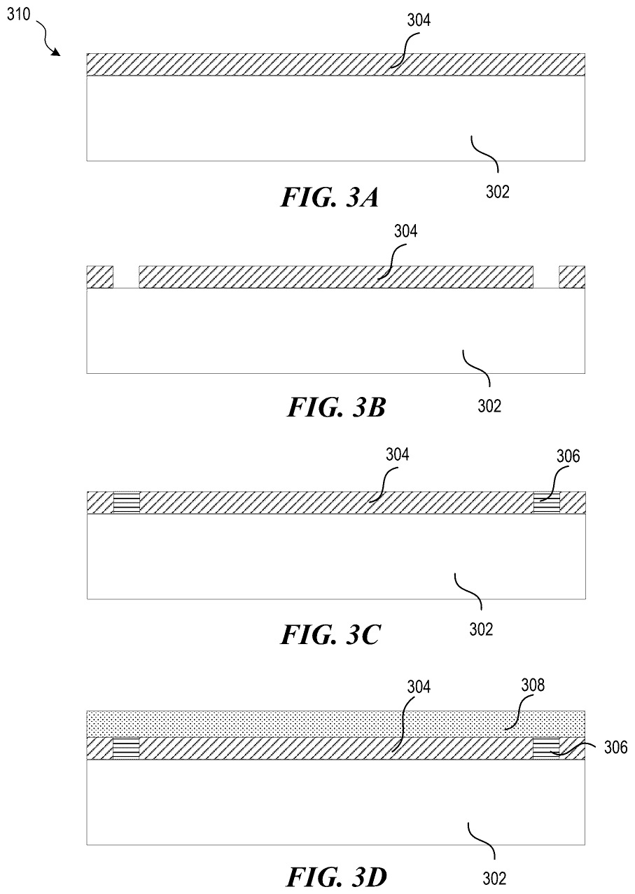

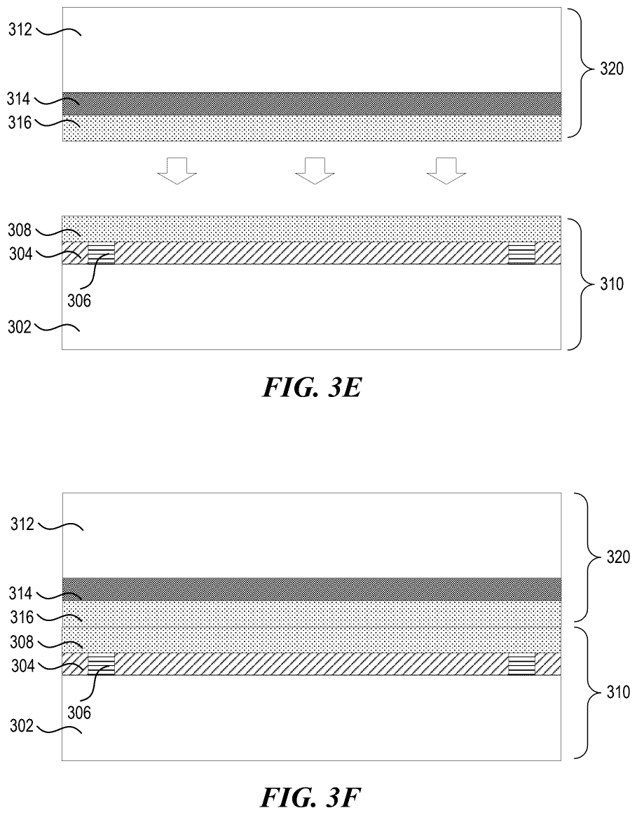

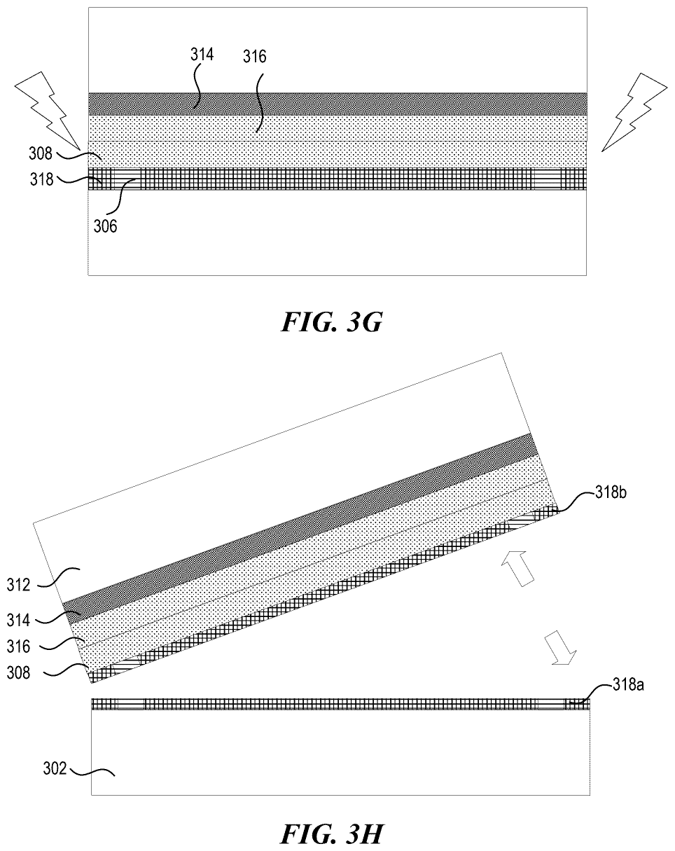

FIGS. 3A to 3H are partially schematic, cross-sectional side views of semiconductor wafers during another semiconductor wafer bonding and debonding processes in accordance with various embodiments of the present technology. In particular, FIGS. 3A to 3D illustrate steps of fabricating a carrier wafer 310 having a dielectric layer 304 with vias 306. The process of carrier wafer 310 starts from depositing a continuous dielectric layer 304 on a frontside surface of a substate 302. The continuously coated dielectric layer 304 can be made of materials including silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Specifically, the dielectric layer 304 can be deposited using a thin film deposition technique such as CVD technique, PVD technique, ALD technique, and/or other processes that are proper in the flow. Here, the dielectric layer 304 may have a thickness ranging from 10 nm to 100 μm. FIG. 2B shows that the dielectric layer 304 can be patterned, e.g., in regions close to the edge of the carrier wafer 310. The patterning of the dielectric layer 304 can be done by forming a patterned hard mask layer there above. The patterned hard mask structure can be fabricated by depositing a continuous hard mask layer and then patterning the hard mask layer using photolithography techniques and etching techniques such as wet etching and/or dry plasma etching techniques. Once the patterned hard mask is ready, another etching process such as an isotropic etching process (e.g., wet chemical etching) or an anisotropic etching process (e.g., reactive ion etching (RIE)) can be conducted to remove exposed materials from the dielectric layer 304. As shown in FIG. 3B, the dielectric layer 304 can be etched through its thickness. In some other examples, the dielectric layer 304 may not be fully etched along its thickness direction. For example, a time controlled etching process can be utilized to partially remove materials (e.g., 50% material removal along the thickness direction) from the dielectric layer 304 through exposed hard mask regions.

In a next step, electrically conductive materials such as copper, tungsten, aluminum, gold, silver, nickel, or their alloys can be filled into the patterned regions of the dielectric layer 304 to form vias 306. The conductive materials can be further planarized, e.g., using a CMP process, to coplanar its top surface with the frontside surface of the dielectric layer 304. In some examples, the dielectric layer 304 can be patterned through the frontside surface of the carrier wafer 301. As a result, the vias 306 can be distributed across the front side surface of the dielectric layer 304. FIG. 3D shows that a metal layer 308 can be further deposited above the dielectric layer 304. The metal layer 308 can be made of materials including titanium, tantalum, tungsten, copper, aluminum, or a combination thereof, and is electrically connected to the vias 306. In this example, the metal layer 308 has a flat frontside surface and a thickness ranging from 100 nm to 500 μm.

FIGS. 3E and 3F illustrate steps of bonding a product wafer 320 with the carrier wafer 310. Here, the product wafer can be similar to the product wafer 140 described in FIG. 1B. For example, the product wafer 320 includes a dielectric layer 314 deposited above its substrate 312, the dielectric layer 314 including device structures such as transistors, passive components, and/or electrical interconnections embedded therein. In addition, the product wafer 320 includes a metal layer 316 disposed above the dielectric layer 314. The metal layer 316 can be made of titanium, tantalum, tungsten, copper, aluminum, or a combination thereof. In this example, as shown in FIG. 3F, the product wafer 320 is bonded on the carrier wafer 130 through forming metal-metal bonds, e.g., using a hybrid bonding (also refers as fusion bonding or direct bonding) process, at the interface between the metal layers 316 and 308.

In some examples, a stack of semiconductor device layers can be bonded on the carrier wafer 310. For example, multiple product wafers can be stacked onto each other and bonded to the carrier wafer 310, after the product wafer 320 is bonded to the carrier wafer 310 as described in FIG. 3E. Specifically, the substrate 312 of the product wafer 320 can be thinned front its backside, e.g., using wafer grinding processes such as the mechanical grinding process and/or the CMP process. After that, another product wafer can be bonded to the thinned product wafer 320, e.g., through bonding a frontside surface of the additional product wafer to the backside surface of the product wafer 320 to form a F2B bonding interface therebetween. These processes can be repeated multiple times to form a stacked semiconductor device layers above the carrier wafer 310.

FIGS. 3G and 3H illustrate steps of debonding the product wafer 320 from the carrier wafer 310. In this example, a voltage can be applied to the bonded wafer edge during a wafer debonding process. As shown in FIG. 3G, the applied voltage can be delivered close to the bonded metal layers 308 and 316. Because the metal layers 308 and 316 are electrically connected to the vias 306, the applied voltage can be transferred to the vias 306. Here, the voltage can generate localized electrical field around the vias 306 and breakdown the dielectric layer 304, which is labeled as break down dielectric layer 318. The dielectric layer breakdown happens when the applied voltage is high enough to ionize the atoms or molecules of the dielectric layer 304, leading to a sudden increase in electrical conductivity and imperfect the dielectric material. In this example, the applied voltage can range from 1V to 10V. In this example, the dielectric layer 318 may include defects or imperfections such as voids, holes, and/or grain boundaries that can significantly impact the strength of the dielectric layer and facilitate a wafer debonding process.

As shown in FIG. 3H, various debonding techniques such as mechanical debonding, laser debonding, chemical debonding, thermal debonding, and/or UV release debonding can be used in this process to break the break down dielectric layer 318. The break down dielectric layer 318 facilitates the wafer debonding process because it structurally less stable and requires a lower debond force to detach the product wafer 320 from the carrier wafer 310, which in turn achieves a higher debonding process yield. After the debonding process, residue dielectric layers 318a and 318b are disposed on frontside surfaces of the carrier wafer 310 and the product wafer 320, respectively. In a downstream cleaning/planarization process, the residue dielectric layer 318a and 318b can be removed using a wet chemical cleaning process or a CMP process. Further, the carrier wafer 310 can be reused for another wafer bonding process. In some examples, the debonded product wafer 320 may include a stack of semiconductor device layers with multiple permanent bonded interfaces disclose therebetween.

In some examples, the debonded product wafer 320 can be sent to downstream processes to complete a semiconductor device. The semiconductor device may include one or more metal layers (e.g., layers 308 and 316) deposited above a dielectric layer (e.g., layer 314). In addition, the semiconductor device may include one or more layers subjected to corrosive chemistry or one or more debonded surfaces that underwent corrosive chemistry. For example, the semiconductor device may include the weakened dielectric layer 318b that is disposed above the metal layer 308. Here, the dielectric layer 318b may include a plurality of vias (e.g., the vias 306).

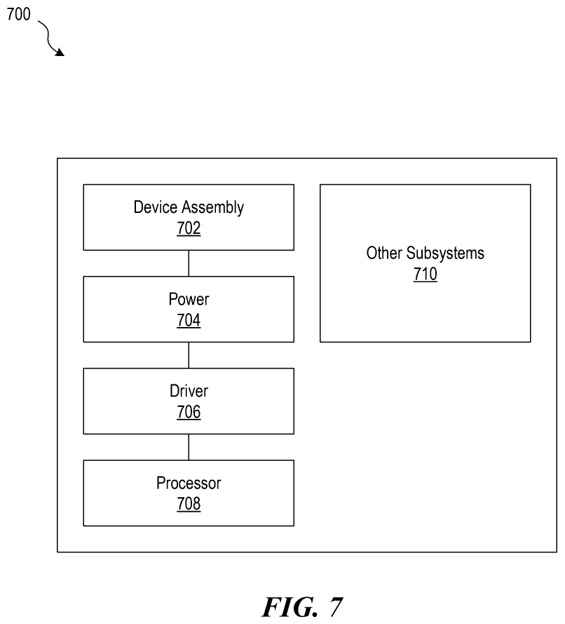

In the present technology, the buried dielectric layer in the carrier wafer can have various patterns, in order to facilitate the wafer bonding and debonding processes. For example, the dielectric layer 304 of the carrier wafer 310 can be patterned and have the metal layer 308 deposited therein and there above. In some other examples, the dielectric layer 304 and the metal layer 308 can be coplanar to form a frontside surface of the carrier wafer 310 that includes both dielectric regions and metal regions. This configuration can assist in forming a strong hybrid bonding interface including metal-metal bonds and dielectric-dielectric bonds between a product wafer and a carrier wafer. FIGS. 4A to 4C illustrate partially schematic top down views of example carrier wafers having different patterns of dielectric layer 304, in accordance with various embodiments of the present technology. FIG. 7A shows dielectric layer 406a as stripe lines aligned in parallel. Each of the dielectric layer 406a stripe lines may have a width ranging from 1 μm to 5 cm and extends to the edge of carrier wafer. In addition, FIG. 7B shows that the dielectric layer 406b can be in a shape of cross over stripe lines. As shown, the stripe lines of dielectric layer 406b can be central divergence to the edge of the carrier wafer. In addition, FIG. 7C shows that the dielectric layer 406c can be in a checkboard pattern, within which the stripe lines extend to the edge of the carrier wafer. In the present technology, the dielectric layers 406a, 406b, and 406c can be respectively patterned into the structures illustrated in FIGS. 7A to 7C. Other metal layers 404a, 404b, and 404c can be respectively deposited into and above the corresponding patterned dielectric layers.

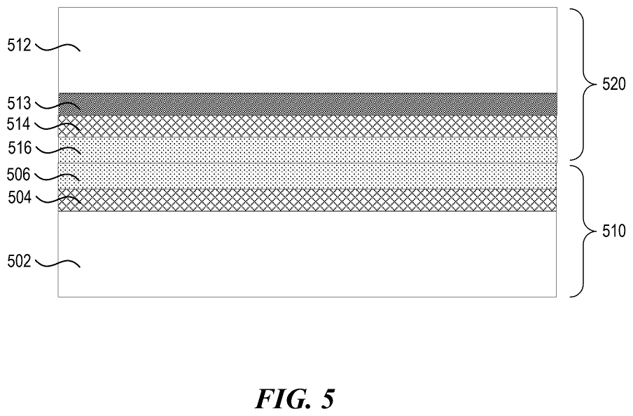

FIG. 5 is a partially schematic, cross-sectional view of bonded semiconductor wafers each having a corrosion-susceptible metal layer in accordance with various embodiments of the present technology. In this example, a product wafer 520 is bonded to a carrier wafer 510. The carrier wafer 510 includes a metal layer 506 disposed above the frontside surface of the substrate 502 and a metal layer 504 that is buried/disposed under the metal layer 106. Here, the metal layer 504 is corrosion-susceptible and can be corroded to form corrosion regions therein. The corrosion portion may extend internally from the edge of the carrier wafer 510. As shown in FIG. 5, the product wafer 520 includes a dielectric layer 513 deposited above its substrate 512, and a dielectric layer 513 having device structures such as transistors, passive components, and/or electrical interconnections embedded therein. In addition, the product wafer 520 includes another corrosion-susceptible metal layer 514 and a metal layer 516 disposed there above.

In this example, metal-metal bonds are formed at the bonding interface between the metal layers 516 and 506. Similar to the metal layer 204 described in FIG. 2E, each of the metal layers 504 and 514 can interact with a corrosive gas and form corrosion regions therein. Here, corrosive gases can be introduced to the exposed metal layers 504 and 514 at the edge of bonded wafers. Corrosion regions can be formed not only in the metal layer 504, but also in the metal layer 514. A downstream wafer debonding process can detach the product wafer 520 from the carrier wafer 510, through either one of the metal layers 504 and 514.

In some other examples, the product wafer 520 may include a stack of semiconductor device layers disposed in the substrate 512 of the product wafer 520. Specifically, the stack of semiconductor device layers can be disposed at the frontside surface of the substrate 512 and close to the dielectric layer 513. In this example, the stack of semiconductor device layers can be formed by sequentially conducting a product wafer substrate backside grinding process and a F2B semiconductor bonding process.

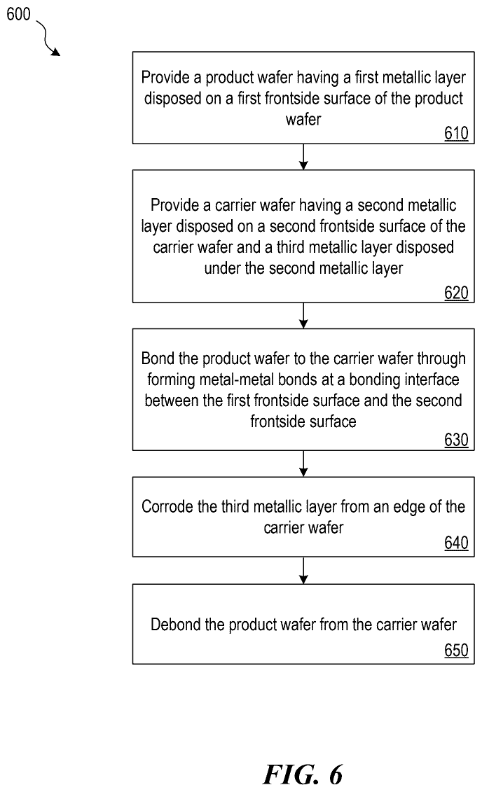

FIG. 6 shows a flow chart illustrating a method 600 for bonding and debonding semiconductor wafers in accordance with various embodiments of the present technology. The method 600 includes providing a product wafer having a first metal layer disposed on a first frontside surface of the product wafer, at 610. For example, the product wafer 220 can be provided for the wafer bonding process. The product wafer 220 includes the metal layer 216 deposited on a frontside surface of the product wafer 220.

The method 600 also includes providing a carrier wafer having a second metal layer disposed on a second frontside surface of the carrier wafer and a third metal layer disposed under the second metal layer, at 620. For example, the carrier wafer 210 can be used for the wafer bonding process. In particular, the carrier wafer 210 includes the substrate 202, the corrosion-susceptible metal layer 204, and the metal layer 206 disposed above the metal layer 204.

In addition, the method 600 includes bonding the product wafer to the carrier wafer through forming metal-metal bonds at a bonding interface between the first frontside surface and the second frontside surface, at 630. For example, the product wafer 220 can be boned to the carrier wafer 210 by aligned their frontside surfaces and forming metal-metal bonds between the metal layers 206 and 216. In this example, a hybrid bonding (also refers as fusion bonding or direct bonding) process can be adopted for the wafer bonding.

Further, the method 600 includes corroding the third metal layer from an edge of the carrier wafer, at 640. For example, corrosive gases can be flowed to exposed portion of the metal layer 204 at the edge of the carrier wafer 210, as shown in FIG. 2F. The corrosive gases can be chlorine, hydrogen, fluorine, or a combination thereof. Moreover, the corrosive gases can cause chemical interactions with the material of metal layer 204, forming corrosion regions including etch by-products therein. The corrosion regions of the corroded metal layer 208 extends from the edge to the center of the carrier wafer 210.

Lastly, the method 600 includes debonding the product wafer from the carrier wafer, at 650. For example, the product wafer 220 can be debonded from the carrier wafer 210, as shown in FIG. 2G. Various debonding techniques such as mechanical debonding, laser debonding, chemical debonding, thermal debonding, and/or UV release debonding can be used in this process to break the corroded metal layer 208, therefore detaching the product wafer 220 from the carrier wafer 210.

Any one of the semiconductor devices and semiconductor device assemblies described above with reference to FIGS. 1 to 6 pertains to the field of semiconductor device fabrication and, more specifically, to a novel technique that significantly enhances the efficiency and reliability of bonding processes used in the assembly of integrated circuits. This technique is particularly applicable to the bonding of chiplets within systems-in-package (SiP), which is a critical step in the creation of compact and high-performance multi-chip modules. The present technique is also highly relevant to wafer-on-wafer bonding, a process that is instrumental in the vertical integration of memory and storage devices, thereby enabling the production of high-density configurations that are essential for advanced computing applications. Furthermore, the present technique is adeptly suited for the manufacturing of three-dimensional dynamic random-access memory (3D-DRAM) and 3D NAND flash memory, where it facilitates the vertical stacking and connection of memory cells, resulting in substantial improvements in data storage capacity and access speeds. The versatility of the present technique allows for its application across various semiconductor fabrication processes, thereby addressing the growing demand for miniaturization and enhanced performance in the electronics industry.

Any one of the semiconductor devices and semiconductor device assemblies described above with reference to FIGS. 1 to 6 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the wafer bonding and debonding processes described above with reference to FIGS. 1 to 6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 700 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A bonded semiconductor structure, comprising:
a product wafer having a first metal layer disposed on a first frontside surface of the product wafer; and
a carrier wafer having a second metal layer disposed on a second frontside surface of the carrier wafer and a third metal layer disposed under the second metal layer,
wherein the first metal layer is bonded to the second metal layer by metal-metal bonds disposed at a bonding interface between the first frontside surface and the second frontside surface, and
wherein the third metal layer includes a corrosion portion extending from an edge of the carrier wafer to a center of the carrier wafer.

2. The bonded semiconductor structure of claim 1, wherein the third metal layer is made of materials comprising tungsten, copper, aluminum, or a combination thereof, and wherein the product wafer includes one or more semiconductor device layers.

3. The bonded semiconductor structure of claim 1, wherein the corrosion portion of the third metal layer comprises copper chloride (CuCl₂), tungsten hexachloride (WCl₆), aluminum trichloride (AlCl₃), dimeric aluminum chloride (Al₂Cl₆), and/or a combination thereof.

4. The bonded semiconductor structure of claim 1, wherein the first metal layer and the second metal layer each comprises materials including tungsten, copper, aluminum, gold, silver, nickel, platinum, palladium, tin, indium, titanium, or their alloys.

5. The bonded semiconductor structure of claim 1, wherein the third metal layer is made of materials different to the first metal layer and the second metal layer.

6. The bonded semiconductor structure of claim 1, wherein the third metal layer has a thickness ranging from 10 nm to 100 um.

7. The bonded semiconductor structure of claim 1, further comprising a first dielectric layer disposed on the first frontside surface of the product wafer, a second dielectric layer disposed on the second frontside surface of the carrier wafer.

8. The bonded semiconductor structure of claim 7, further comprising dielectric-dielectric bonds disposed at the bonding interface.

9. The bonded semiconductor structure of claim 1, further comprises metal silicide at the bonding interface, the metal silicide including a same metallic element to the third metal layer, wherein the metal silicide including tungsten silicide, copper silicide, and/or aluminum silicide.

10. A bonded semiconductor structure, comprising:
a product wafer having a first metal layer disposed on a first frontside surface of the product wafer;
a carrier wafer having a second metal layer disposed on a second frontside surface of the carrier wafer and a first dielectric layer disposed under the second metal layer; and
one or more vias disposed in the first dielectric layer and connected to the second metal layer, the one or more vias are disposed close to an edge of the carrier wafer,
wherein the first metal layer is bonded to the second metal layer by metal-metal bonds disposed at a bonding interface between the first frontside surface and the second frontside surface, and
wherein at least a portion of the first dielectric layer breaks down and shows a conductive state.

11. The bonded semiconductor structure of claim 10, wherein the first dielectric layer is made of materials including silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

12. The bonded semiconductor structure of claim 10, wherein the one or more vias are made of materials including copper, tungsten, aluminum, gold, silver, nickel, or their alloys, and wherein the product wafer includes one or more semiconductor device layers.

13. The bonded semiconductor structure of claim 10, wherein the first dielectric layer has a thickness ranging from 10 nm to 100 um.

14. The bonded semiconductor structure of claim 10, wherein the one or more vias have a thickness equal to or less than the first dielectric layer.

15. A method of forming a semiconductor structure, comprising:
providing a product wafer having one or more semiconductor device layers and a first metal layer disposed on a first frontside surface of the product wafer;
providing a carrier wafer having a second metal layer disposed on a second frontside surface of the carrier wafer and a third metal layer disposed under the second metal layer;
bonding the product wafer to the carrier wafer through forming metal-metal bonds at a bonding interface between the first frontside surface and the second frontside surface;
corroding the third metal layer from an edge of the carrier wafer; and
debonding the product wafer from the carrier wafer.

16. The method of claim 15, wherein corroding the third metal layer comprises flowing corrosive chemistry to an edge of the carrier wafer and facilitating chemical reactions between the corrosive chemistry and the third metal layer.

17. The method of claim 16, wherein corroding the third metal layer comprises forming a corrosion portion in the third metal layer, the corrosion portion extending from the edge of the carrier wafer towards a center of the carrier wafer.

18. The method of claim 16, wherein the corrosive chemistry comprises chlorine, hydrogen, fluorine, or a combination thereof.

19. The method of claim 17, wherein forming the corrosion portion in the third metal layer comprises forming at least one of copper chloride (CuCl₂), tungsten hexachloride (WCl₆), aluminum trichloride (AlCl₃), and dimeric aluminum chloride (Al₂Cl₆).

20. The method of claim 15, wherein corroding the third metal layer comprises conducting a local laser ablation process at a wafer edge region to form metal silicide comprising tungsten silicide, copper silicide, and/or aluminum silicide, close to the bonding interface.
